(19) United States
(12) Patent Application Publication
(10) Pub. No.: US 2023/0178375 A1
(43) Pub. Date: Jun. 8, 2023

(54) METHODS FOR FORMING WORK FUNCTION MODULATING LAYERS

(71) Applicant: Applied Materials, Inc., Santa Clara, CA (US)

(72) Inventors: Kunal Bhatnagar, Chandler, AZ (US); Wei Liu, San Jose, CA (US); Shashank Sharma, Fremont, CA (US); Archana Kumar, Mountain View, CA (US); Mohith Verghese, Phoenix, AZ (US); Jose Alexandro Romero, Scottsdale, AZ (US)

(73) Assignee: Applied Materials, Inc., Santa Clara, CA (US)

(21) Appl. No.: 17/541,582

(22) Filed: Dec. 3, 2021

(51) Int. Cl. H01L 21/28; H01L 29/49; H01L 29/40; H01L 21/285; H01L 21/3215

(52) U.S. Cl. CPC H01L 21/28088; H01L 21/3215; H01L 21/28556; H01L 29/401; H01L 29/4966

(57) ABSTRACT

Method of forming film stacks and film stacks for electronic devices are described herein. The methods comprise depositing a molybdenum nucleation layer on a gate oxide layer; depositing a molybdenum layer on the molybdenum nucleation layer; and performing a plasma nitridation process to insert nitrogen atoms into the molybdenum layer to form a work function modulating layer having an effective work function ≤ 4.5 eV. The plasma nitridation process comprises exposing the molybdenum layer to a radical-rich plasma comprising one or more of N₂ or NH₃. Some methods further comprise one or more of annealing the work function modulating layer, depositing a conductive layer on the work function modulating layer, or performing an etch process.

### TECHNICAL FIELD

Embodiments of the disclosure generally relate to methods for forming work function modulating layers. In particular, embodiments of the disclosure pertain to methods for forming work function modulating layers having a reduced effective work function.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. An example of such a device is a complementary metal-oxide-semiconductor (CMOS) field effect transistor (FET) or MOSFET. A gate electrode is part of an integrated circuit. For example, a MOSFET comprises a gate structure disposed between source and drain regions that are formed in the semiconductor substrate. The gate structure or stack generally comprises a gate electrode and a gate dielectric. The gate electrode is disposed over the gate dielectric to control a flow of charge carriers in a channel region that is formed between drain and source regions beneath the gate dielectric.

In manufacturing, three-dimensional (3D) structures, such as fin field effect transistors (FinFETs), gate all around structures (GAAs), dynamic random access memory (DRAM) word lines, and the like, are made by atomic layer deposition of titanium nitride (TiN) and tungsten (W) stacks. As microelectronic device dimensions have shrunk, there has been an increase in word line resistance where the metal fill material comprises tungsten. Current processes use a metal fill material comprising molybdenum to attempt to reduce word line resistance. Known processes using molybdenum as the metal fill material exhibit a high effective work function. Some approaches have employed nitrogen implantation processes to reduce effective work function in microelectronic devices. However, known implantation processes induce increased flat band voltage (Vf_{b}), leakage issues and degradation in electronic device performance.

Accordingly, there is a need for methods of forming work function modulating layers having a reduced effective work function and processes for decreasing Vf_{b}.

### SUMMARY

One or more embodiments of the disclosure are directed to a method of forming a film stack. The method comprises depositing a molybdenum nucleation layer on a gate oxide layer; depositing a molybdenum layer on the molybdenum nucleation layer; and performing a plasma nitridation process to insert nitrogen atoms into the molybdenum layer to form a work function modulating layer. The plasma nitridation process comprises exposing the molybdenum layer to a radical-rich plasma comprising one or more of N₂ or NH₃.

Another embodiment of the disclosure is directed to a method of forming a film stack. The method comprises depositing a molybdenum nucleation layer on a gate oxide layer; depositing a molybdenum layer on the molybdenum nucleation layer; and performing a plasma nitridation process to insert nitrogen atoms into the molybdenum layer to form a work function modulating layer having an effective work function ≤ 4.5 eV. The plasma nitridation process comprises exposing the molybdenum layer to a radical-rich plasma comprising one or more of N₂ or NH₃. The method further comprises annealing the work function modulating layer.

Further embodiments of the disclosure are directed to an electronic device. The electronic device comprises a film stack on a substrate surface. The film stack comprises a molybdenum nucleation layer on a gate oxide layer; a work function modulating layer comprising molybdenum nitride on the molybdenum nucleation layer, the work function modulating layer having an effective work function ≤ 4.5 eV; and a conductive layer comprising molybdenum on the work function modulating layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates an electronic device with a film stack on a substrate in accordance with one or more embodiments of the disclosure;

FIG. 2 illustrates an electronic device with a film stack on a substrate in accordance with one or more embodiments of the disclosure;

FIG. 3 illustrates the electronic device of FIG. 2 after etching a portion of a conductive layer;

FIG. 4 illustrates the electronic device of FIG. 2 after etching a portion of the conductive layer and a portion of a work function modulating layer; and

FIG. 5 illustrates a process flow diagram of a method of forming a film stack in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

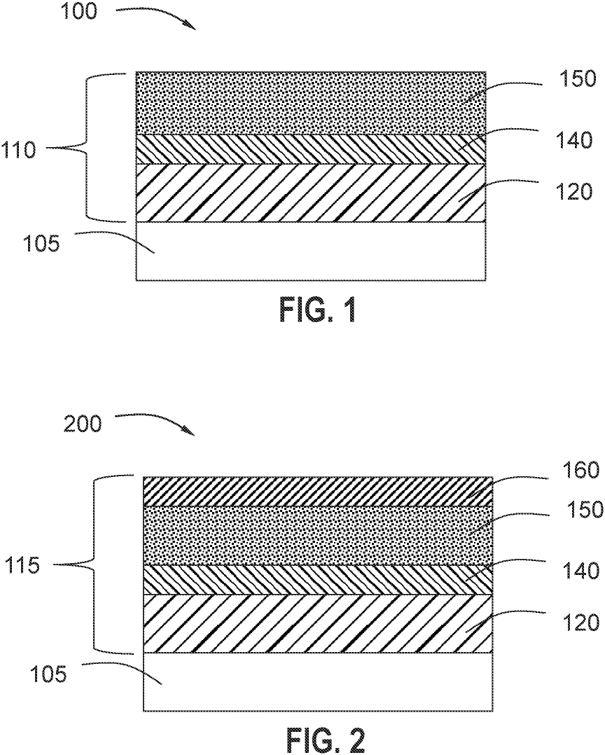

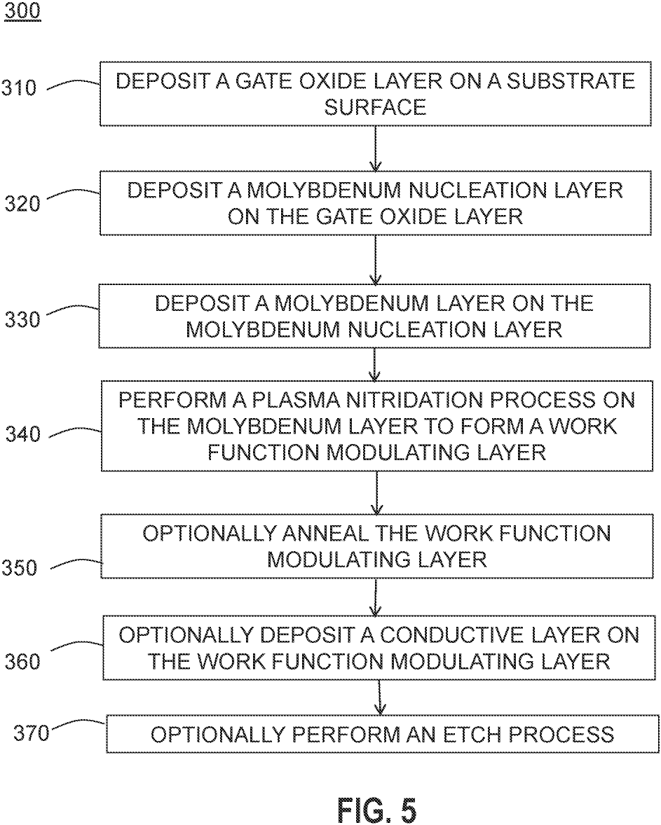

Referring to FIGS. 1-4, an electronic device 100, 200 is shown. FIG. 5 illustrates a method 300 of forming a film stack 110, 115 having any of the features of one or more embodiments shown in FIGS. 1-4. The electronic devices 100, 200 described herein may be used in MOSFET, FinFET, GAA, DRAM word line, and like applications.

FIG. 1 illustrates the electronic device 100 having a film stack 110 on a substrate 105. The film stack 110 comprises a gate oxide layer 120 formed on the substrate 105 according to operation 310 of method 300. In one or more embodiments, the gate oxide layer 120 electrically insulates other layers/films of the film stack 110 from the substrate 105. In one or more embodiments, the gate oxide layer 120 comprises a metal oxide. In some embodiments, the gate oxide layer 120 comprises silicon oxide. In further embodiments, the gate oxide layer 120 is an in-situ steam generated (ISSG) silicon oxide layer formed by utilizing H₂ and O₂ gases. In one or more embodiments, the gate oxide layer 120 has a thickness in a range of from 20 Å to 50 Å.

In one or more embodiments, the film stack 110 comprises a molybdenum nucleation layer 140 formed on the gate oxide layer 120 according to operation 320 of method 300. In some embodiments, the molybdenum nucleation layer 140 has a thickness in a range of from 5 Å to 20 Å. Without being bound by any particular theory of operation, the molybdenum nucleation layer 140 improves quality (e.g., such as interface state density, accumulation capacitance, frequency dispersion, and leakage current) of the interface between the gate oxide layer 120 and a molybdenum layer formed according to operation 330 of method 300.

Embodiments of the disclosure advantageously provide electronic devices 100, 200 having a reduced effective work function. Traditionally, DRAM cells have recessed high work function metal structures in buried word line (bWL) structure. In a DRAM device, a bit line is formed in a metal level situated above the substrate, while the word line is formed at the polysilicon gate level at the surface of the substrate. In a buried word line (bWL) device, a word line is buried below the surface of a semiconductor substrate using a metal as a gate electrode. Current DRAM buried word line (bWL) processes involve titanium nitride (TiN) and tungsten (W) stacks. Without being bound by any particular theory of operation, known electronic devices (i.e., DRAM devices) have an effective work function ≥ 4.8 eV. Embodiments of the disclosure advantageously provide film stacks 110, 115 including a work function modulating layer 150 having an effective work function ≤ 4.5 eV.

In one or more embodiments, the film stack 110 includes the work function modulating layer 150 formed on the molybdenum nucleation layer 140. The work function modulating layer 150 is formed according to operations 330 and 340 of method 300. In some embodiments, the work function modulating layer 150 is formed by depositing a molybdenum layer on the molybdenum nucleation layer 140 at operation 330. In some embodiments, the molybdenum layer is deposited by atomic layer deposition (ALD). In some embodiments, the molybdenum layer is deposited by a thermal ALD process. In one or more embodiments, the molybdenum layer is deposited at a pressure in a range of from 30 torr to 50 torr.

In further embodiments, the method 300 comprises, at operation 340, performing a plasma nitridation process on the molybdenum layer deposited at operation 330 to form the work function modulating layer 150. Without being bound by any particular theory of operation, there is no degradation in device performance in the electronic devices 100, 200 after performing the plasma nitridation processes described herein. In one or more embodiments, the plasma nitridation process is performed to insert nitrogen atoms into an interface formed between the gate oxide layer 120 and the molybdenum nucleation layer 140. In one or more embodiments, the plasma nitridation process is performed to insert nitrogen atoms into the molybdenum layer to form the work function modulating layer 150. In one or more embodiments, the plasma nitridation process is performed to insert nitrogen atoms into an interface between any of the layers/films in the electronic device 100, 200. In one or more embodiments, the work function modulating layer 150 comprises a metal nitride. In one or more embodiments, the work function modulating layer 150 comprises molybdenum nitride. In some embodiments, the plasma nitridation process comprises exposing the molybdenum layer to a radical-rich plasma comprising one or more of N₂ or NH₃. As used in this manner, the term “radical-rich plasma” means that greater than or equal to about 95%, 98% or 99% of the plasma used in the plasma nitridation process of operation 340 comprises nitrogen radicals. In one or more embodiments, the radical-rich plasma further comprises argon. In one or more embodiments, the radical-rich plasma is generated using one or more of an inductively coupled plasma (ICP), microwave plasma or remote plasma source.

The plasma nitridation process may be a decoupled plasma nitridation (DPN) process performed in a DPN chamber such as CENTURA® DPN chamber, available from Applied Materials, Inc., located in Santa Clara, Calif. in some embodiments, the plasma nitridation process comprises exposing the molybdenum layer to nitrogen plasma, to form the work function modulating layer 150, which allows nitrogen radicals or nitrogen atoms to be incorporated within the work function modulating layer 150, throughout the thickness of the work function modulating layer 150. During the plasma nitridation process, nitrogen atoms may form metastable bonds with oxygen (O). Gases that may be used in the plasma process include nitrogen containing gas, such as nitrogen (N₂), ammonia (NH₃), or mixtures thereof. In one example, the nitrogen gas is ammonia (NH₃) mixed with about 3 % to about 8 % of nitrogen (N₂). The plasma nitridation process may not change a thickness of the work function modulating layer 150 as a result of the nitrogen incorporation to vacancies and defects in the as-deposited work function modulating layer 150.

The plasma nitridation process may be performed for between about 10 seconds and about 300 seconds, at a temperature of between about 0° C. and about 500° C.

In one or more embodiments, the plasma nitridation process includes an optional thermal nitridation process performed to further insert nitrogen atoms into vacancies and defects in the work function modulating layer 150. The thermal nitridation process may include a thermal anneal process in an ammonia (NH₃) ambient, performed in a rapid thermal processing (RTP) chamber, such as RADOX™ chamber, available from Applied Materials, Inc., located in Santa Clara, Calif. The thermal nitridation process may be performed for between about 10 seconds and about 300 seconds, at a temperature of between about 300° C. and about 1100° C., and at a pressure of between about 10 Torr and 740 Torr.

According to one or more embodiments, the method 300, at operation 350, optionally comprises annealing the work function modulating layer 150. In one or more embodiments, any aspects or variations of operations 340 and 350 of method 300 may be performed in combination. Without intending to be bound by any theory of operation, annealing the work function modulating layer 150 passivates the remaining chemical bonds into the work function modulating layer 150. In one or more embodiments, annealing the work function modulating layer 150 may include a spike thermal anneal process in a nitrogen (N₂) and argon (Ar) ambient, performed in a rapid thermal processing (RTP) chamber, such as RADOX™ chamber, available from Applied Materials, Inc., located in Santa Clara, Calif. The spike thermal anneal process may be performed for between about 1 second and about 30 seconds, at a temperature of between about 300° C. and about 1100° C., and at a pressure of between about 10 Torr and 740 Torr.

In some embodiments, annealing the work function modulating layer 150 occurs in a molecular hydrogen (H₂) environment at a temperature in a range of 300 °-C to 1100° C. without plasma. In some embodiments, annealing the work function modulating layer 150 occurs at a temperature in a range of 300° C. to 1100° C. in a molecular hydrogen (H₂) plasma comprising H* radicals. Without intending to be bound by any particular theory of operation, performing one or more of the plasma nitridation process or annealing process at operations 340 and 350, respectively results in an electronic device having a decreased flat band voltage (V_{fb}). In some embodiments, annealing the work function modulating layer 150 decreases a flat band voltage (V_{fb}) by an amount in a range of 100 mV to 600 mV.

In the embodiments described herein, the methods 300 of forming film stacks and film stacks for electronic devices 100, 200 are provided. The properties of the work function modulating layer 150 may be well controlled. For example, the plasma nitridation process in operation 340 may be controlled to provide a nitrogen incorporation in the work function modulating layer 150 of between about 3 atomic% and about 20 atomic%, to achieve better structural stabilization than a lower nitrogen incorporation. The optional anneal process in operation 350 may also be controlled to provide grains in the work function modulating layer 150 having a size larger than about 20 Å, to reduce leakage currents through the gate oxide layer 120.

In some embodiments, a density of the electronic device 100, 200 is measured at an interface formed between the molybdenum nucleation layer 140 and the work function modulating layer 150 is measured (i.e., interface density). In some embodiments, the interface density is in a range of from about 1.5 x 10¹² cm-²eV-¹ to about 6.0 x 10¹² cm-²eV-¹. In some embodiments, the interface density of the electronic device 100, 200 is greater than an interface density of a comparative electronic device without the work function modulating layers described herein.

In some embodiments, the electronic device 200 comprises a film stack 115 on the substrate 105. The film stack 115 comprises the film stack 110 illustrated in FIG. 1 with additional layers/films formed thereon, as shown in FIG. 2. In accordance with method 300, in some embodiments, the film stack 115 comprises the gate oxide layer 120 formed on the substrate 105 according to operation 310, the molybdenum nucleation layer 140 formed on the gate oxide layer 120 according to operation 320, and the work function modulating layer 150 formed on the molybdenum nucleation layer 140 according to operations 330 and 340. In one or more embodiments, the film stack 115 comprises a conductive layer 160 formed on the work function modulating layer 150 according to operation 360 of method 300. The conductive layer 160 can be any suitable material. In some embodiments, the conductive layer 160 comprises a metal deposited by any suitable deposition process. In some embodiments, the conductive layer 160 comprises platinum deposited by physical vapor deposition (PVD).

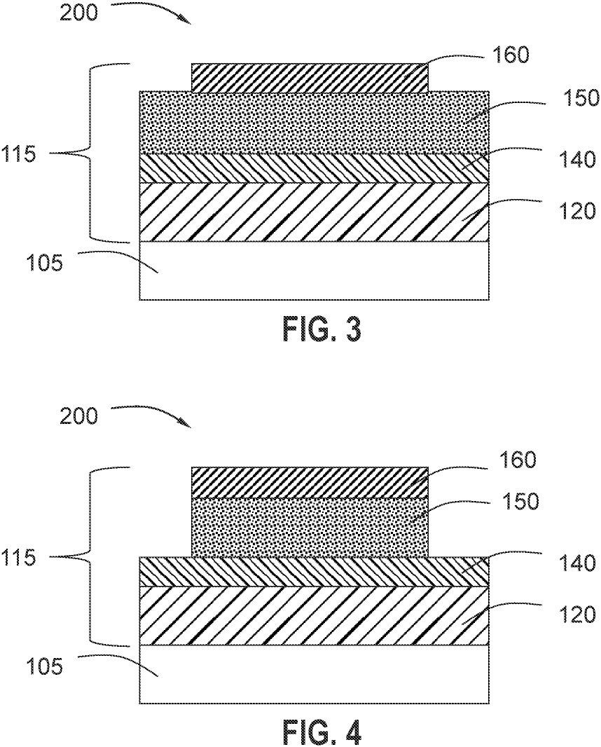

FIG. 3 illustrates the electronic device 200 of FIG. 2 after etching a portion of the conductive layer 160 according to operation 370 of method 300. FIG. 4 illustrates the electronic device 200 of FIG. 2 after etching a portion of the conductive layer 160 and a portion of a work function modulating layer 150 according to operation 370 of method 300. The optional etch process according to operation 370 may be performed on any layer/film of the electronic device 100, 200. Referring again to FIG. 3, a portion of the conductive layer 160 may be etched, and/or the conductive layer 160 may be selectively removed, by any process known to one of skill in the art, including, but not limited to, wet etching, plasma-based sputter etching, chemical etching, Siconi® etching, reactive ion etching (RIE), high density plasma (HDP) etching, chemical-mechanical planarization (CMP) and the like. In one or more embodiments, substantially all of the conductive layer 160 remains on the substrate 105. As used in this manner, the term “substantially all of the conductive layer 160” means that greater than or equal to about 95%, 98% or 99% of the conductive layer 160 optionally formed in operation 360 (see FIG. 5) remains after etching.

Referring again to FIG. 4, a portion of the conductive layer 160 and a portion of a work function modulating layer 150 are etched according to operation 370 of method 300. In one or more embodiments, substantially all of the conductive layer 160 or the work function modulating layer 150 remains on the substrate 105. As used in this manner, the term “substantially all of the conductive layer 160 or the work function modulating layer 150” means that greater than or equal to about 95%, 98% or 99% of the conductive layer 160 or the work function modulating layer 150 formed in operations 340 and 360 (see FIG. 5) remains after etching.

In some embodiments, one or more operations of the method 300 described herein are repeated. Some or all of the processes and methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

Embodiments of the disclosure are directed to a non-transitory computer readable medium. In one or more embodiments, the non-transitory computer readable medium includes instructions that, when executed by a controller of a processing chamber, causes the processing chamber to perform the operations of any of the processing methods described herein. In one or more embodiments, the processing chamber performs the operations of method 300. In one or more embodiments, the processing chamber performs the operations of: depositing a gate oxide layer on a substrate surface; depositing a molybdenum nucleation layer on the gate oxide layer; depositing a molybdenum layer on the molybdenum nucleation layer; performing a plasma nitridation process on the molybdenum layer to form a work function modulating layer; optionally annealing the work function modulating layer; optionally depositing a conductive layer on the work function modulating layer; and optionally performing an etch process.

According to one or more embodiments, the substrate is subjected to processing prior to and/or after forming the layers/films. This processing can be performed in the same chamber or in one or more separate processing chambers. In one or more embodiments, the method 300 occurs in the same processing tool.

Several well-known cluster tools which may be adapted for the present disclosure are the Olympia®, the Continuum®, and the Trillium®, all available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), plasma treatment, etch, pre-clean, chemical clean, thermal treatment such as RTP, plasma nitridation, degas, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrates are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Spatially relative terms, such as “beneath,” “below,” “lower,” “above,” “upper” and the like, may be used herein for ease of description to describe one element or feature’s relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below”, or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a film stack, the method comprising:
depositing a molybdenum nucleation layer on a gate oxide layer;
depositing a molybdenum layer on the molybdenum nucleation layer; and
performing a plasma nitridation process to insert nitrogen atoms into the molybdenum layer to form a work function modulating layer, the plasma nitridation process comprising exposing the molybdenum layer to a radical-rich plasma comprising one or more of N₂ or NH₃.

2. The method of claim 1, wherein the radical-rich plasma further comprises argon.

3. The method of claim 2, wherein the radical-rich plasma is generated using one or more of an inductively coupled plasma (ICP), microwave plasma or remote plasma source.

4. The method of claim 3, wherein the molybdenum layer is deposited by atomic layer deposition (ALD).

5. The method of claim 1, further comprising annealing the work function modulating layer.

6. The method of claim 5, wherein annealing the work function modulating layer occurs in a molecular hydrogen (H₂) environment at a temperature in a range of 300° C. to 1100° C. without plasma.

7. The method of claim 5, wherein annealing the work function modulating layer occurs at a temperature in a range of 300° C. to 1100° C. in a molecular hydrogen (H₂) plasma comprising H* radicals.

8. The method of claim 5, wherein annealing the work function modulating layer decreases a flat band voltage (V_{fb}) by an amount in a range of 100 mV to 600 mV.

9. The method of claim 1, further comprising forming the gate oxide layer on a substrate surface.

10. The method of claim 9, wherein the gate oxide layer comprises silicon oxide.

11. The method of claim 10, wherein the gate oxide layer is an in-situ steam generated (ISSG) silicon oxide layer.

12. The method of claim 1, further comprising depositing a conductive layer on the work function modulating layer.

13. The method of claim 12, wherein the conductive layer comprises platinum deposited by physical vapor deposition (PVD).

14. The method of claim 1, wherein the work function modulating layer has an effective work function ≤ 4.5 eV.

15. The method of claim 1, wherein the gate oxide layer has a thickness in a range of from 20 Å to 50 Å, and the molybdenum nucleation layer has a thickness in a range of from 5 Å to 20 Å.

16. A method of forming a film stack, the method comprising:
depositing a molybdenum nucleation layer on a gate oxide layer;
depositing a molybdenum layer on the molybdenum nucleation layer;
performing a plasma nitridation process to insert nitrogen atoms into the molybdenum layer to form a work function modulating layer having an effective work function ≤ 4.5 eV, the plasma nitridation process comprising exposing the molybdenum layer to a radical-rich plasma comprising one or more of N₂ or NH₃; and
annealing the work function modulating layer.

17. The method of claim 16, wherein annealing the work function modulating layer occurs in a molecular hydrogen (H₂) environment at a temperature in a range of 300° C. to 1100° C. without plasma.

18. The method of claim 16, wherein annealing the work function modulating layer occur at a temperature in a range of 300° C. to 1100° C. in a molecular hydrogen (H₂) plasma comprising H* radicals.

19. The method of claim 16, wherein annealing the work function modulating layer decreases a flat band voltage (V_{fb}) by an amount in a range of 100 mV to 600 mV.

20. An electronic device comprising:
a film stack on a substrate surface, the film stack comprising:
a molybdenum nucleation layer on a gate oxide layer;
a work function modulating layer comprising molybdenum nitride on the molybdenum nucleation layer, the work function modulating layer having an effective work function ≤ 4.5 eV; and
a conductive layer comprising molybdenum on the work function modulating layer.
